(19) United States
(12) Patent Application Publication
(10) Pub. No.: US 2004/0115956 A1
(43) Pub. Date: Jun. 17, 2004

(54) Substrate treating device and substrate treating method

(76) Inventor: Hiroshi Ishida, Mainato-ku (JP)

Correspondence Address: Rader Fishman & Grauer, Suite 501, 1233 20th Street N W, Washington, DC, 20036, US

(21) Appl. No.: 10/473,161

(22) PCT Filed: Jun. 24, 2002
(86) PCT No.: PCT/JP02/06297

(30) Foreign Application Priority Data
Jun. 25, 2001 (JP) 2001-191978

(51) Int. Cl. H01L 21/31; H01L 21/469

(52) U.S. Cl. 438/782

(57) ABSTRACT

Since a first processing unit group that forms an interlayer insulating film under atmospheric pressure and a second processing unit group that performs, for example, electron beam or UV irradiation, CVD, cleaning and the like under reduced pressure or under increased pressure are configured to be integrally disposed, a time period necessary for processing can be shortened, particularly in the damascene process, and footprint per processing capacity can be reduced. Furthermore, as the processing time period is shortened in such manner, even when, for example, a porous film is used as an insulating film, the film can be restrained from absorbing moisture in the air thus deterioration in the film quality can be prevented, resulting in forming an insulating film of high quality.

### TECHNICAL FIELD

The present invention belongs to a technical field such as manufacturing of semiconductor devices, and in particular relates to a substrate processing apparatus for forming an interlayer insulating film on a substrate and a method of processing the substrate.

### BACKGROUND ART

In a process of manufacturing a semiconductor device, for example, an interlayer insulating film is formed under atmospheric pressure using a SOD (Spin on Dielectric) system. In the SOD system, according to a sol-gel method or the like, a coating film is spin-coated on a wafer, on which chemical or heat processing is applied, and thereby an interlayer insulating film is formed.

When an interlayer insulating film is formed according to the sol-gel method, first, on a semiconductor wafer (hereinafter referred to as “wafer”), a solution in which colloid of an insulating film material such as TEOS (tetraethoxysilane) dispersed in an organic solvent is supplied. Subsequently, the wafer on which the solution is supplied is subjected to gelling process then solvent substitution followed by baking process and the like.

Meanwhile, in recent years, in order to attain high-speed and high integration of a device, a wiring structure is formed into a multi-layer by laminating insulating films of low dielectric constant into a multi-layer, and wiring is formed according to a damascene process. In the damascene process, a predetermined groove is formed in advance in an interlayer insulating film by means of etching and the like, a conductive wiring material such as Al or Cu is buried into the groove by means of the sputtering method or CVD method. The wiring material piled up outside of the groove is removed by means of CMP technique and the like, and the wiring is formed thereby.

However, in the damascene process, when a time necessary for a series of processing by SOD system such as insulating film coating, gelling, or baking process and a time necessary for forming the metal wiring such as CVD are compared, the time necessary for SOD system is overwhelmingly longer and the number of processes is also larger. Accordingly, in order to attain higher efficiency, it is highly demanded to arrange CVD apparatus and the like in-line to the SOD system.

Furthermore, also from a viewpoint of quality of an insulating film, in the damascene process, there is a problem that since the process requires time in transferring the wafer with an insulating film is formed thereon and being taken out of the SOD system into the CVD apparatus, a condition of the insulating film deteriorates.

In particular, in recent years, in order to attain more high-speed and lower consumption power of devices, in some cases, an insulating film of low dielectric constant such as a porous film having air bubbles therein is used. However, when transferring the substrate into the CVD requires time as mentioned above, moisture in the air may be absorbed in the air bubbles of the porous film, and thereby the film quality may deteriorate.

### DISCLOSURE OF THE INVENTION

In view of the situations such as mentioned above, the object of the present invention is to provide a substrate processing apparatus capable of shortening processing time period necessary for the formation of the insulating film and wiring and maintaining a condition of film high-quality in a coated insulating film, and the processing method therefor.

In order to attain the above object, a first viewpoint of the invention includes, a first processing unit group disposed adjacent to the cassette station having a plurality of first processing units for forming an insulating film on the substrate under an atmospheric pressure, a first transfer unit for transferring the substrate to the plurality of first processing units, a second processing unit group having a plurality of second processing units for processing the substrate with the insulating film being formed thereon, under at least one of a reduced pressure and an increased pressure, a plurality of load lock chambers connected to each of the plurality of second processing units, capable of controlling an internal pressure thereof and a second transfer unit for transferring the substrate between the first processing unit group and the plurality of load lock chambers.

According to the invention, for example, the first processing unit group in which the interlayer insulating film is formed under atmospheric pressure, is structured to be provided integrally with the second processing unit group in which, processes such as electron beam and UV irradiation, CVD and cleaning are performed under reduced pressure or under increased pressure. Accordingly, particularly in the damascene process, the processing time period can be shortened and the footprint per processing capacity can be reduced. Furthermore, when the processing time period is shortened, even when, for example, the porous film is used as the insulating film, the deterioration of the film quality caused by moisture in the air being absorbed can be prevented, resulting in forming the insulating film of high-quality.

According to one embodiment of the invention, the second processing units are arranged in a horizontal direction, and the second transfer unit transfers the substrate in the horizontal direction. Furthermore, alternatively, the second processing units are multi-tiered in a vertical direction, and the second transfer unit transfers the substrate in the vertical direction. Thereby, whether the second processing units are arranged in a horizontal direction or in a vertical direction, the substrate can be transferred to the second processing unit.

According to another embodiment of the invention, the first processing unit group having at least a coating unit for spin-coating a processing solution on the substrate and a heating unit for heating the substrate. The second processing unit group has at least one of an electron beam irradiation unit for curing the insulating film and a UV irradiation unit for reforming a surface state of the insulating film. Thereby, the formation of the insulating film in the first processing unit group and the post processing such as electron beam or UV irradiation in the second processing unit group can be performed successively. Accordingly, the processing time period can be shortened and an insulating film of high quality can be formed.

According to still another embodiment of the invention, the second processing unit group has a CVD apparatus. Thereby, for example, in the damascene process, the processing time period for forming the interlayer insulating film and the wiring can be shortened, resulting in an efficient processing. Furthermore, by shortening the processing time period, condition of the insulating film can be well maintained. Accordingly, an insulating film of high quality can be formed.

According to another embodiment of the invention, the present invention further comprises a transfer arm for transferring the substrate between the second processing unit and the load lock chamber. With such configuration, since a substrate in the load lock chamber can be transferred to the second processing unit, the substrate can successively be transferred from the first processing unit through the second transfer unit and the load lock chamber to the second processing unit. Such transfer arm is preferably disposed, for example, in the load lock chamber. Furthermore, in order to transfer the substrate between the first transfer unit and the second transfer unit, a plurality of pins may be disposed to at least one unit of the first processing unit group.

A second viewpoint of the invention includes a first processing unit group having a plurality of first processing units for forming an insulating film on the substrate under an atmospheric pressure, a second processing unit group having a plurality of second processing units for processing the substrate with the insulating film being formed thereon, under at least one of a reduced pressure and an increased pressure, a plurality of load lock chambers connected to each of the plurality of second processing units, capable of controlling an internal pressure thereof, a transfer unit for transferring the substrate between the first processing unit group and the plurality of load lock chambers, a transfer arm disposed in the load lock chamber for transferring the substrate being transferred by the transfer unit to the second processing unit and a controller for controlling a processing order such that after the insulating film is formed in the plurality of the first processing units, the transfer unit transfers the substrate to the load lock chamber and the transfer arm transfers the substrate to the second processing unit, so that the substrate is processed in the second processing unit.

According to the invention, the formation of the insulating film in the first processing unit group and the post processing such as electron beam or UV irradiation in the second processing unit group can be successively performed. Accordingly, the processing time period can be shortened and an insulating film of high quality can be formed. Furthermore, when CVD apparatus and the like is provided for example in the second processing unit, the processing time period necessary for forming the interlayer insulating film and the wiring can be shortened particularly in the damascene process, which results in efficient processing. Still further, by shortening the processing time period, even when, for example, a porous film is used as the insulating film, another interlayer insulating film laminated adjacent to the porous film can be restrained from being absorbed. Accordingly, an insulating film of high quality can be formed.

A third viewpoint of the invention comprises a first processing unit group having a plurality of first processing units for forming an insulating film on the substrate under an atmospheric pressure, a second processing unit group having a plurality of second processing units for processing the substrate with the insulating film being formed thereon under at least one of a reduced pressure and an increased pressure, a plurality of load lock chambers connected to each of the plurality of second processing units with an inside pressure thereof capable of being controlled and a cassette station disposed adjacent to the first processing units having a plurality of cassettes being linearly arranged for accommodating the substrates.

According to the configuration of the present invention, the first processing unit group in which an insulating film is formed in a single cassette station and the second processing unit group performing for example, the electron beam or UV irradiation or CVD processing under reduced pressure or under increased pressure are connected. Accordingly, in damascene process in particular, the time period for processing can be shortened and the footprint per processing capacity can be reduced. Furthermore, by shortening the time period for processing as such, the condition of the insulating film can be maintained well, resulting in forming an insulating film of high quality.

A substrate processing method according to the invention comprising, forming an insulating film on the substrate under an atmospheric pressure in a first processing unit group, transferring the substrate to an intermediate delivery portion disposed in the first processing unit group and transfers the substrate to a second processing unit group disposed adjacent to the first processing unit group, transferring the substrate from the intermediate delivery portion to the second processing unit group and irradiating an electron beam on the substrate under a reduced pressure in the second processing unit group.

According to the present invention, formation of the insulating film under atmospheric pressure in the first processing unit group and the electron beam irradiation under reduced pressure in the second processing unit group are successively performed. Furthermore, transfer of the substrate from the first processing unit group to the second processing unit group is performed through the intermediate delivery portion. According to such successive processing under atmospheric pressure and under reduced pressure, the processing time period can be shortened and an insulating film of high quality can be formed. Here, a plurality of first processing units processing the substrate under atmospheric pressure is supposed to be disposed in the first processing unit group. Furthermore, a plurality of first processing units that process the substrate under reduced pressure is supposed to be disposed in the second processing unit group.

Furthermore, according to the present invention, the substrate with the insulating film formed thereon may be heated under atmospheric pressure in the first processing unit group, or the substrate with the insulating film is formed thereon may be heated under reduced pressure in the second processing unit group. When the substrate is subjected to heating under atmospheric pressure or under reduced pressure, the processing corresponding to, in particular, the damascene process can be applied and the processing time period thereof can be shortened; accordingly, an insulating film of high quality can be formed.

A still another viewpoint of the invention comprises a first processing unit group having a plurality of first processing units for forming an insulating film on the substrate under an atmospheric pressure, CVD apparatus for forming another insulating film on the substrate by CVD and a transfer unit that transfers the substrate between the first processing unit group and the CVD apparatus, the present invention comprises a method of forming an interlayer insulating film on the substrate in the first processing unit in the first processing unit group, and transferring the substrate with the insulating film being formed thereon to the CVD apparatus by the transfer unit and forming an additional insulating film.

According to the present invention, the formation of the insulating film in an atmospheric pressure processing unit and the formation of other insulating films for upper and lower layers by the CVD apparatus can successively be performed owing to the transfer of the substrate by the transfer unit. Accordingly, in the damascene process in particular, the processing time period can be shortened and the footprint per processing capacity can be reduced.

### BRIEF DESCRIPTION OF THE DRAWINGS

FIG. 1 is a plan view showing an entire configuration of an insulating film processing system according to one embodiment of the invention.

FIG. 2 is a front view of the insulating film processing system shown in FIG. 1.

FIG. 3 is a rear view of the insulating film processing system shown in FIG. 1.

FIG. 4 is a sectional view of a load lock chamber according to one embodiment.

FIG. 5 is an exploded perspective view of a transition unit according to one embodiment.

FIG. 6 is a plan view of an SOD coating process unit according to one embodiment.

FIG. 7 is a sectional view of the SOD coating unit shown in FIG. 6.

FIG. 8 is a plan view of a low oxygen curing and cooling unit.

FIG. 9 is a sectional view of the low oxygen curing and cooling unit shown in FIG. 8.

FIG. 10 is a block diagram showing a control system of an insulating film processing system.

FIG. 11 is a flowchart showing a series of processing steps in the insulating film processing system (part 1).

FIGS. 12A through 12E are sectional views showing steps of forming a semiconductor element according to one embodiment (part 1 thereof).

FIGS. 13A through 13E are sectional views showing steps of forming a semiconductor element according to one embodiment (part 2 thereof).

FIGS. 14A and 14B are sectional views showing steps of forming a semiconductor element according to one embodiment (part 3 thereof).

FIG. 15 is a flowchart showing another embodiment of the processing steps.

FIG. 16 is a flowchart showing still another embodiment of the processing steps.

FIG. 17 is a plan view showing an entire configuration of an insulating film processing system according to another embodiment.

FIG. 18 is a perspective view showing an entire configuration of still another insulating film processing system.

FIG. 19 is a perspective view showing a modification example of the insulating film processing system in FIG. 18.

### BEST MODE FOR CARRYING OUT THE INVENTION

In the following, embodiments for carrying out the present invention will be explained with reference to the drawings.

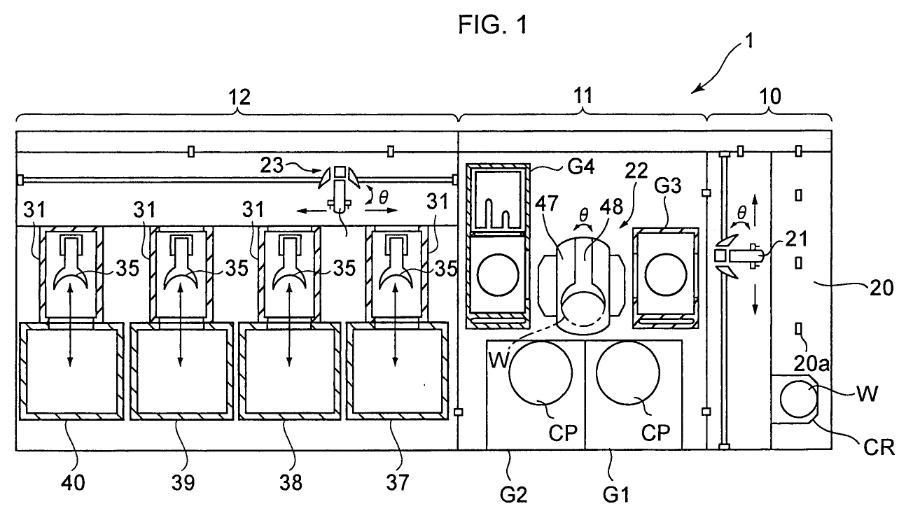

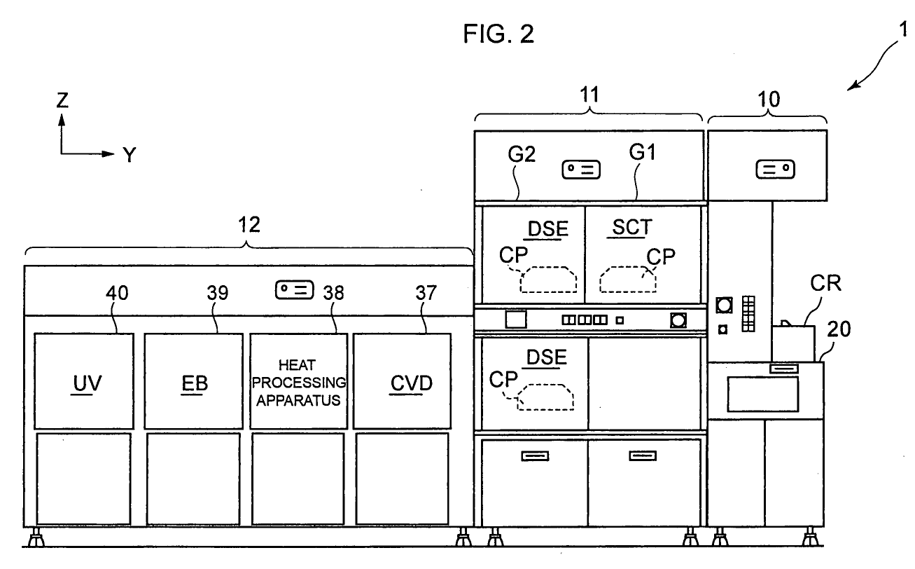

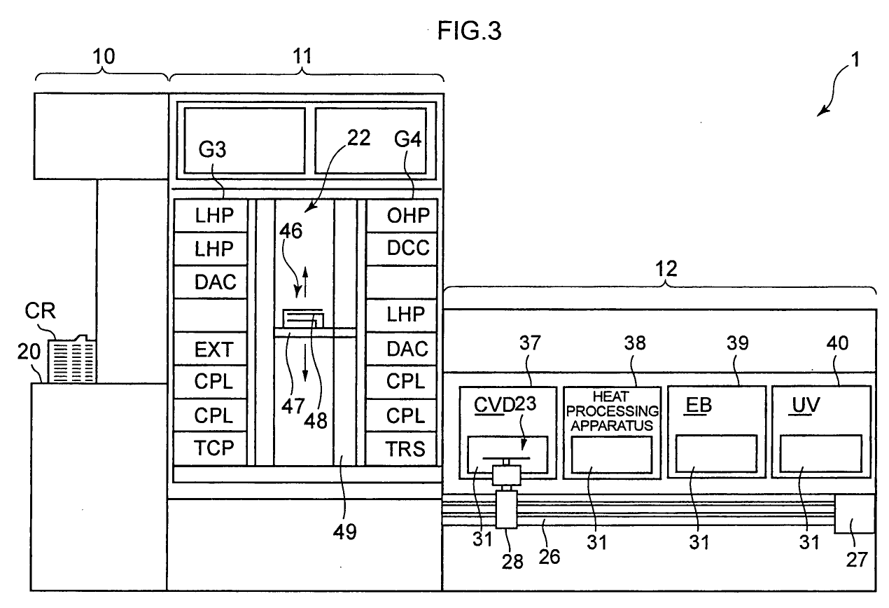

FIG. 1 through FIG. 3 are diagrams showing an entire configuration of an insulating film processing system according to one embodiment of the invention. That is, FIG. 1 is a plan view of the present invention, FIG. 2, is a front view; and FIG. 3, is a rear view thereof.

In an insulating film processing system 1, a cassette station 10 which transfers a semiconductor wafer W as a substrate into the system from the outside or out of the system by a unit of a plurality of, for example, twenty-five, by use of a wafer cassette CR, and transfers the wafer W into or out of the wafer cassette CR, an atmospheric pressure processing block 11 comprises various kinds of sheet type processing units in predetermined positions is multi-tiered, the sheet type processing units applying a predetermined processing, one wafer at a time, under atmospheric pressure in the SOD coating step, and a reduced pressure/increased pressure processing block 12 that is formed by arranging various kinds of sheet type processing units that applies a predetermined processing to the wafer W under reduced pressure or under increased pressure are integrally connected. In the following, having the pressure higher than atmospheric pressure is called “increased pressure”.

In the cassette station 10, as shown in FIG. 1, at positions of projections 20a on a cassette mounting table 20, a plurality of, for example, up to four of wafer cassettes CR are disposed in line in an X direction with a respective entrance directed toward the atmospheric pressure processing block 11; and a wafer transfer mechanism 21 capable of moving in a cassette arrangement direction (X direction) and in a wafer arrangement direction (Z vertical direction) in which the wafers accommodated in the wafer cassette CR are arranged, makes a selective access to the respective wafer cassettes CR. Furthermore, the wafer transfer mechanism 21 is configured rotatable in a θ direction and accessible to a transferring and cooling plate (TCP) in a multi-tiered unit portion of a third processing apparatus group G3 on the atmospheric pressure processing block 11 side as described later.

In the atmospheric pressure processing block 11, as shown in FIG. 1, at the center thereof, a vertical transfer type vertical transfer unit 22 is disposed, and a plurality of groups of atmospheric pressure processing units are disposed multi-tiered in surroundings thereof. In this example, four groups of G1, G2, G3 and G4 are constituted multi-tiered. Multi-tiered units of a first and a second processing apparatus groups G1 and G2 are disposed side by side on a front side of the system (front side in FIG. 1), a multi-tiered unit of a third processing apparatus group G3 is disposed adjacent to the cassette station 10, and a multi-tiered unit of a fourth processing apparatus group G4 is disposed adjacent to a reduced pressure/increased pressure processing block 12.

As shown in FIG. 2, in the first processing apparatus group G1 and in the second processing apparatus group G2, an SOD coating unit (SCT) in which, in a cup CP, a wafer W, on which an insulating film material is supplied is disposed on a spin chuck, the wafer is rotated and thereby an uniform insulating film is formed on the wafer, and a solvent exchange unit (DSE) in which, in the cup CP, the wafer W is placed on the spin chuck, exchanging chemical liquid such as HMDS and heptane are supplied, and thereby a solvent in the insulating film coated on the wafer is exchanged to another solvent before drying are stacked in two-tiers from the bottom.

In the first processing apparatus group G1, the SOD coating unit (SCT) is disposed in an upper tier. In a lower tier of the first processing apparatus group G1, an SOD coating unit (SCT), a solvent exchange unit (DSE) and the like may be disposed when necessary.

As shown in FIG. 3, in the third processing apparatus group G3, the transferring and cooling plate (TCP), two cooling u nits (CPL), an extension unit (EXT), an aging unit (DAC), and two low temperature heating units (LHP) are multi-tiered sequentially from the bottom.

In the fourth processing apparatus group G4, a transition unit (TRS), two cooling units (CPL), an aging unit (DAC), a low temperature heating unit (LHP), a low oxygen curing and cooling unit (DCC) and a low oxygen high temperature heating unit (OHP) are disposed multi-tiered.

The transferring and cooling plate (TCP), though not shown in the drawings, is formed into a two-tier configuration having a cooling plate for cooling the wafer W in a lower tier and a transferring table in an upper tier for transferring the wafer W between the cassette station 10 and the atmospheric pressure processing block 11. The extension unit (EXT) also transfers the wafer between the cassette station 10 and the atmospheric pressure processing block 11 in a same manner. In the aging unit (DAC), NH₃+H₂O is introduced into a processing chamber capable of being hermetically sealed, the wafer is subjected to aging process, and thereby a film of insulating film material on the wafer W is wet gelled. The cooling unit (CPL) has a cooling plate thereon the wafer W is placed and cools the wafer W. The low temperature heating unit (LHP) has a hot plate heating the wafer W and the wafer is heated at a temperature in the range of, for example, from 100 to 200 degree centigrade (° C.). The low oxygen high temperature heating unit (OHP) has a hot plate on which the wafer is disposed in a processing chamber capable of being hermetically sealed, discharges N₂ uniformly from holes provided in a periphery of the hot plate and exhausts from the center at an upper portion of the processing chamber. And, the wafer is heated in a low oxygen atmosphere and at a high temperature. The transition unit (TRS) will be explained later.

With reference to FIG. 3, the vertical transfer unit 22 is provided inside of a cylindrical support 49, having a wafer transfer mechanism 46 capable of moving up and down in a vertical direction (Z direction). The cylindrical support 49 is connected to a rotating shaft of a motor not shown in the drawing, and, with a rotating driving force of the motor, the shaft is rotated together with the wafer transfer mechanism 46 with the rotating shaft as a center. Accordingly, the wafer transfer mechanism 46 is freely rotatable in a 0 direction. On a transfer base table 47 of the wafer transfer mechanism 46, for example, three tweezers 48 are provided. The tweezers 48 accesses to the atmospheric pressure processing units arranged in the surroundings of the vertical transfer unit 22 and transfer the wafer W with the processing units.

In the reduced pressure/increased pressure processing block 12, on a backside of the system, a horizontal transfer unit 23 for transferring the wafer W is disposed movable in a Y direction along with a rail 26 and rotatable in a 0 direction with a motor 28.

On a front side of the reduced pressure/increased pressure processing block 12, a CVD apparatus 37, a heat processing apparatus 38, an electron beam irradiation unit (EB) 39 and an UV irradiation unit (UV) 40 are arranged side by side in a Y direction. In the CVD apparatus 37, the heat processing apparatus 38, the electron beam irradiation unit (EB) 39 and the UV irradiation unit (UV) 40, the respective processing can be performed under reduced pressure.

To each of the CVD apparatus 37, heat processing apparatus 38, electron beam irradiating unit (EB) 39 and UV irradiation unit (UV) 40, for example, four load lock chambers 31 are connected, respectively, and the horizontal transfer unit 23 is accessible to these load lock chambers 31

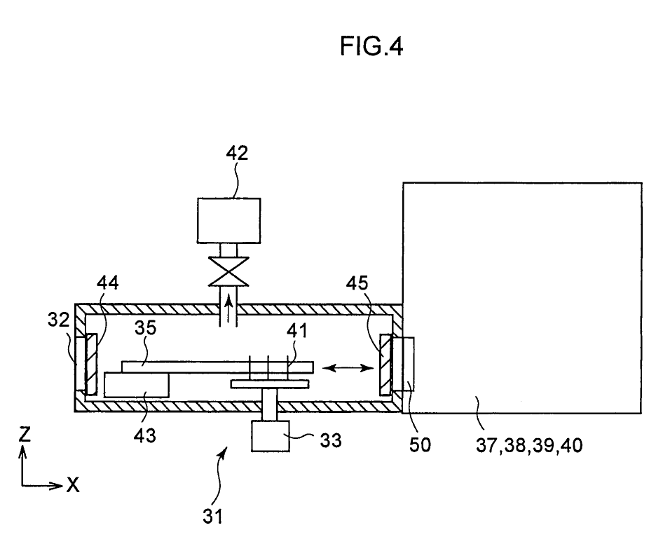

As shown in FIG. 4, on back and front sides of each of the load lock chambers 31, respectively, openings 32 and 50 are formed, and to the openings 32 and 50, gate valves 44 and 45 for hermetically close inside the chamber are provided on respective opening. A transfer arm of the horizontal transfer unit 23 accesses from the opening 32 on the backside and an arm 35 disposed inside accesses to the CVD apparatus 37, heat processing apparatus 38, or an electron beam irradiation unit (EB) 39 from the opening 45 on the front side.

In the load lock chamber 31, elevation pins 41 and the arm 35 are disposed. The elevation pins 41 is movable up and down in a Z direction driven by a raising and lowering cylinder 33, and, by the elevation drive, the wafer W is transferred from the horizontal transfer unit 23 is supported from a back surface side. On the other hand, the arm 35 can be moved in an X direction by means of a moving mechanism not shown, and the wafer W supported by the elevation pins 41 is, transferred to the arm 35 owing to descending drive of the elevation pins 41.

Furthermore, a pressure controller 42 provided in each of the load lock chambers 31 evacuates or pressurizes inside of the chamber so that a pressure thereof may become equal to a reduced pressure condition or become higher than an atmospheric pressure of each of the CVD apparatus 37, heat processing apparatus 38, electron beam irradiation unit (EB) 39 and UV irradiation unit (UV). When the load lock chamber 31 is thus provided to each of the reduced pressure/increased pressure processing units, even the pressure in the respective reduced pressure/increased pressure processing unit is different from each other, pressure control can be easily applied to correspond with each pressure.

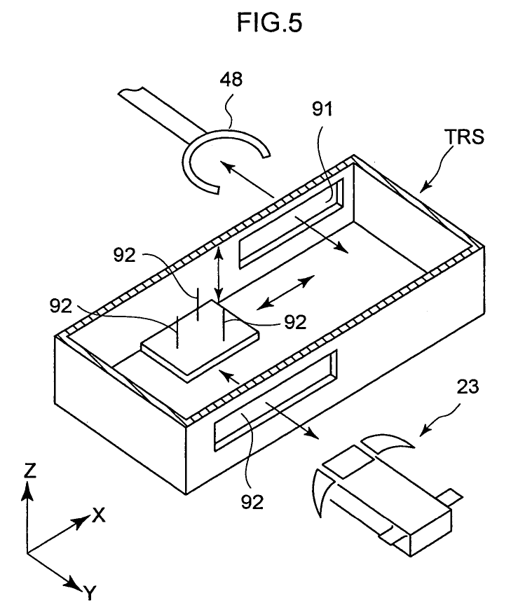

FIG. 5 is an exploded perspective view of the transition unit (TRS) in the fourth processing apparatus group G4. In the transition unit (TRS), for example three supporting pins 92 that support the wafer W can be moved in an X direction and elevated in a Z direction by means of a driving unit not shown. As the driving unit in X and Z directions, belt drive with a stepping motor and the like is used. Furthermore, on both side surfaces of the transition unit (TRS), opening portions 91 are formed. From the opening portions 91, the tweezers 48 and the transfer arm 23 of the horizontal transfer unit are able to enter into and to come out there through. Accordingly, the wafer W is transferred from the tweezers 48 through the supporting pins 92 to the horizontal transfer unit 23 and thereby transferred between the atmospheric pressure processing block 11 and the reduced pressure/increased pressure processing block 12.

In the insulating film processing system 1 according to the present embodiment, examples in which the respective processing apparatus 37, 38, 39 and 40 in the reduced pressure/increased pressure processing block 12 applies the processing under reduced pressure are cited. However, in addition to these, washing apparatus for cleaning the wafer under increased pressure, ashing apparatus and the like for peeling resist to be used in the photo-lithography under reduced pressure can be added in a Y direction.

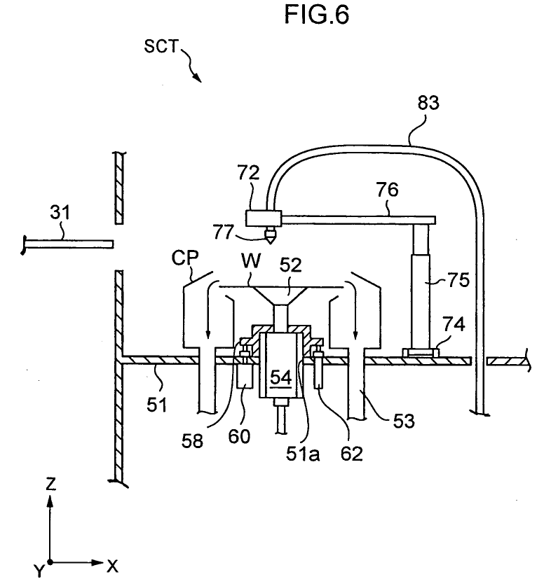

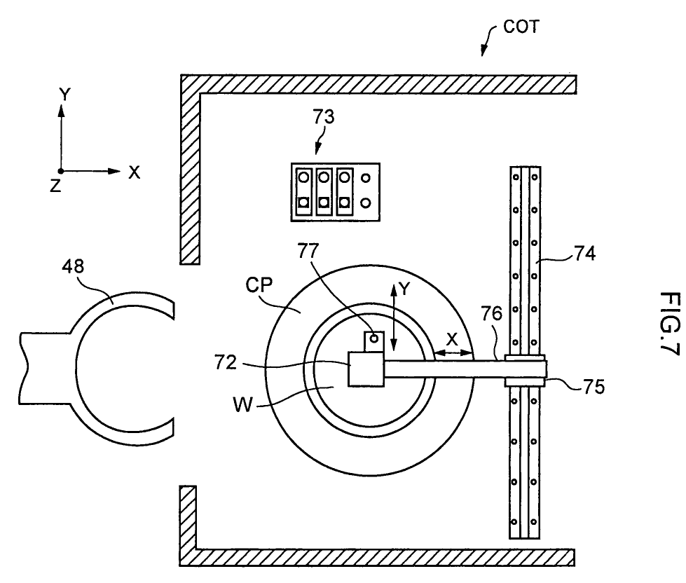

FIG. 6 and FIG. 7 are a sectional view and a plan view of the SOD coating unit (SCT). At a central portion of the SOD coating unit (SCT), an annular cup CP having a waste tube 53 is disposed, and inside of the cup CP, a spin chuck 52 is disposed for horizontally holding the substrate. The spin chuck 52, with the wafer W fixed and held thereto by reduced pressure absorption, is driven to rotate by a driving motor 54. The driving motor 54 is movably disposed at an opening 51a disposed in a unit bottom plate 51, and connected to movement driving means 60 and elevation guiding means 62 configured, for example, with an air-cylinder, through a cap-like flange member 58 made of, for example, aluminum.

To a nozzle 77 that discharges an interlayer insulating film material onto a surface of the wafer W, a supply tube 83 extended from a supply source of the insulating film material (not shown) is connected. The nozzle 77 is detachably attached through a nozzle holder 72 to a tip end of a nozzle scan arm 76. The nozzle scan arm 76 is attached to an upper end portion of a vertical supporting member 75 that is horizontally movable along on a guide rail 74 disposed in one direction (Y direction) on the unit bottom plate 51 and moves in the Y direction integrally with the vertical support member 75 by means of a Y direction driving system which is not shown.

On a side of the cup CP, a nozzle waiting portion 73 where the nozzle 77 stands by is disposed, and a plurality of nozzles corresponding to the kinds of the insulating film materials is provided in the nozzle waiting portion 73, for discharging different kinds of insulating film materials, the coating is performed with the nozzle being exchanged when necessary.

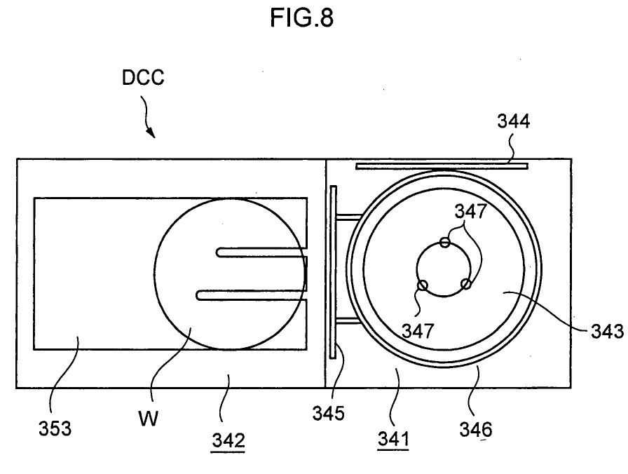

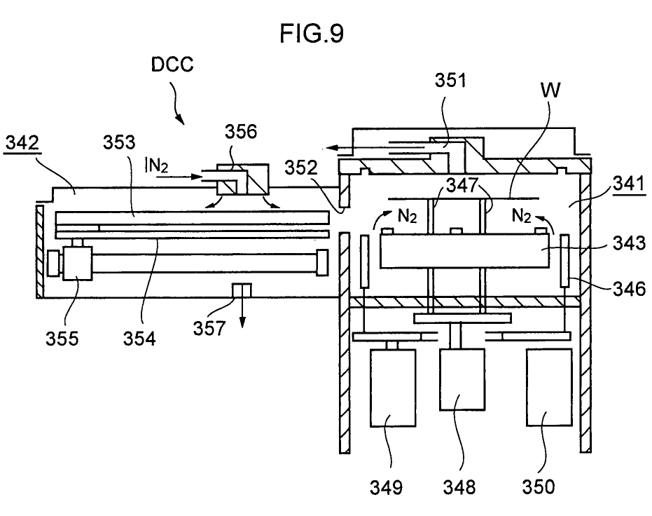

FIG. 8 is a plan view of the low oxygen curing and cooling unit (DCC) and FIG. 9 is a sectional view thereof.

The low oxygen curing and cooling unit (DCC) includes a heating chamber 341 and a cooling chamber 342 disposed adjacently thereto, and the heating chamber 341 has a hot plate 343 whose temperature can be set in a range of from 200° C. to 470° C. The low oxygen curing and cooling unit (DCC) further comprises a gate shutter 344 to be opened when the wafer is transferred to and from the vertical transfer unit 22, and a gate shutter 345 disposed between the heating chamber 341 and the cooling chamber 342, opening and closing the two chambers, and a ring shutter 346 raised together with the second gate shutter 345 while surrounding the wafer W by a perimeter of the hot plate 343. Furthermore, three lift pins 347 are movably provided on the hot plate 343 for lifting and lowering the wafer W being placed thereon. A shielding plate screen may be disposed between the hot plate 343 and the ring shutter 346.

Below the heating chamber 341, a raising and lowering system 348 that raises the lift pins 347, a raising and lowering system 349 that raises the ring shutter 346 together with the second gate shutter 345, and a raising and lowering system 350 that raises and opens the first gate shutter 344 are disposed.

N₂ gas as a purging gas is supplied into the heating chamber 341, from the ring shutter 346 described later. In addition, an exhaust tube 351 is connected to a top portion of the heating chamber 341, and thereby the inside of the heating chamber 341 is evacuated through the exhaust tube 351.

The heating chamber 341 and the cooling chamber 342 are communicated through a communicating opening 352, and a cooling plate 353 on which a wafer W is placed and cooled is constituted movable in a horizontal direction along the guide plate 354 by means of a transferring system 355. Thereby, the cooling plate 353 proceeds through the communicating opening 352 into the heating chamber 341, receives the wafer W heated by the hot plate 343 in the heating chamber 341 from the lift pins 347, transfers the wafer W into the cooling chamber 342, cool the wafer W, thereafter, returns the wafer W on the lift pins 347.

A preset temperature of the cooling plate 353 is in the range of, for example, from 15° C. to 25° C., and an applicable temperature range of the wafer W to be cooled is in the range of, for example, from 200° C. to 470° C.

Furthermore, the cooling chamber 342 is configured so that an inert gas such as N₂ or the like may be supplied therein through a supply tube 356, and furthermore the inside thereof is configured so as to be exhausted through an exhaust tube 357 to the outside thereof. Thereby, the inside of the cooling chamber 342 can maintain a low oxygen concentration atmosphere in a same manner as to the heating chamber 341 (for example, 50 ppm or less).

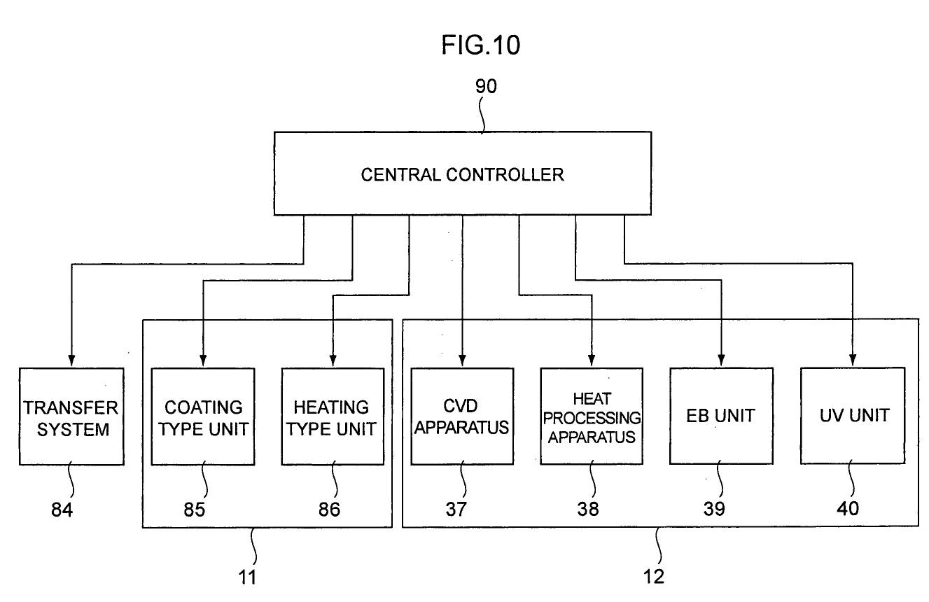

FIG. 10 is a block diagram showing a control system of the insulating film processing system 1. Reference numeral 84 denotes transfer systems such as the above-mentioned wafer transfer mechanism 21, the vertical transfer unit 22, the horizontal transfer unit 23, arm 35 of the load lock chamber 31 etc. Furthermore, reference numeral 85 denotes coating units such as the SOD coating unit (SCT), the solvent exchanging unit (DSE) and the like, and reference numeral 86 denotes the heating unit. Reference numerals 37, 38, 39 and 40 denote the CVD apparatus, heat processing apparatus, electron beam irradiation unit (EB), and UV irradiation unit (UV) respectively.

Each of these units and apparatuses has a separate controller for performing a corresponding processing, which is not shown, and a central controller 90 integrally controls the separate controllers.

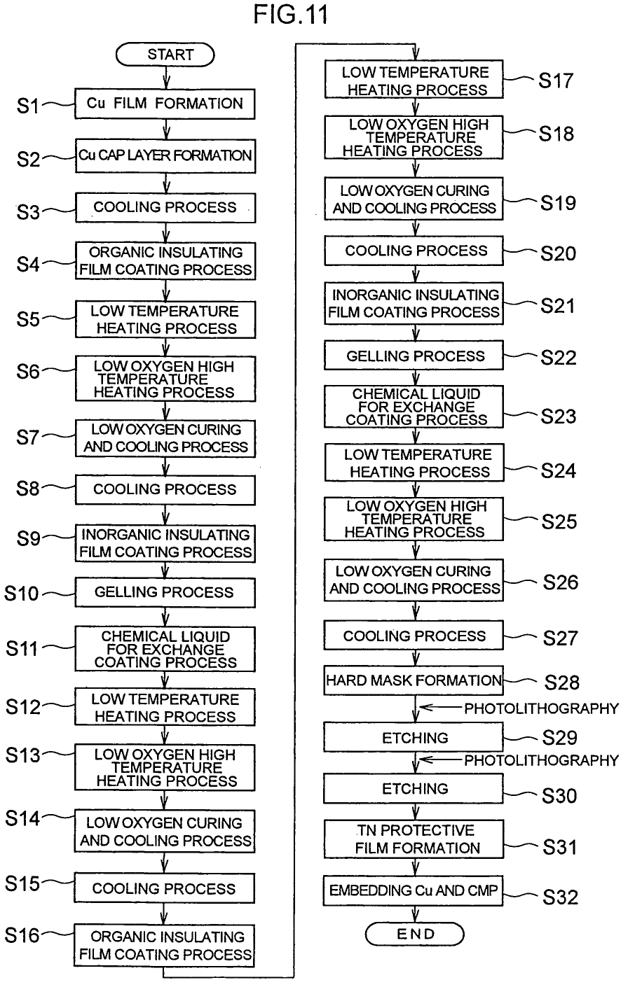

Next, with reference to the flow chart shown in FIG. 11, a series of processing steps of the above-explained insulating film processing system 1 will be explained.

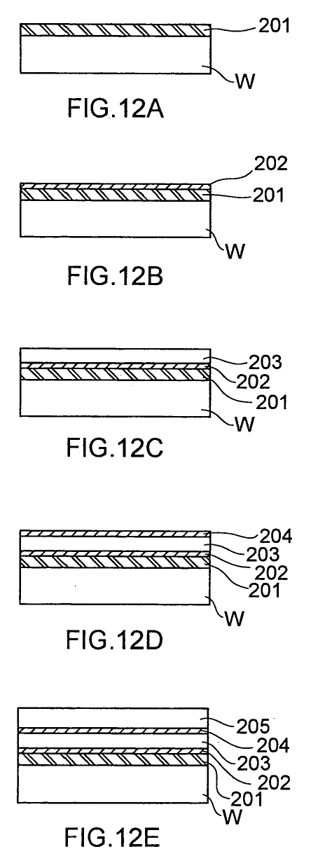

First, a wafer W is transferred from the wafer cassette CR, through the wafer transfer mechanism 21, the extension unit (EXT) of the third processing apparatus group G3, the vertical transfer unit 22, the transition unit (TRS) of the fourth processing apparatus group G4, the horizontal transfer unit 23 and the load lock chamber 31 to the CVD apparatus 37. There, as shown in FIG. 12A, a Cu film 201 as, for example, a bottom layer wiring is formed (Step 1).

Furthermore, in the CVD apparatus 37, as shown in FIG. 12B, an insulating film (Cu cap layer) 202 that protects the Cu film is formed by means of CVD (Step 2). As the Cu cap layer, for example a SiN film or SiC film is formed.

Thereafter, the wafer W is transferred through the load lock chamber 31, the horizontal transfer unit 23, the transition unit (TRS) and the vertical transfer unit 22 into the cooling unit (CPL), where cooling process is performed (Step 3).

Next, the wafer W is transferred through the vertical transfer unit 22 into the SOD coating unit (SC), and there an organic insulating film material of, for example, from 200 to 500 nm, more preferably of substantially 300 nm is coated on the wafer W by means of spin coat method under atmospheric pressure (Step 4). Thereby, as shown in FIG. 12C, an organic insulating film 203 is formed on the wafer W. In this example, SILK is used as the organic insulating film material.

Subsequently, the wafer W is transferred through the vertical transfer unit 22 to the low temperature heating unit (LHP) and there subjected to the low temperature heating, for example, at substantially 150° C. for substantially 60 seconds (Step 5).

Then, the wafer W is transferred through the vertical transfer unit 22 to the low oxygen high temperature heating unit (OHP), and, in the low oxygen atmosphere, the wafer W is heated, for example, at a high temperature in the range of from 200° C. to 350° C. for substantially 60 seconds (Step 6).

Subsequently, the wafer W is transferred through the vertical transfer unit 22 to the low oxygen curing and cooling unit (DCC), and, in the low oxygen atmosphere, the wafer W is heated at a high temperature of substantially 450° C. for substantially 60 seconds followed by cooling to substantially 23° C. (Step 7).

Next, the wafer W is transferred through the vertical transfer unit 22 to the cooling unit (CPL) and cooled there to substantially 23° C. (Step 8).

In the next place, the wafer W is transferred through the vertical transfer unit 22 to the SOD coating unit (SCT) and there an inorganic insulating film material of a thickness in the range of, for example, from substantially 300 to 1100 nm, more preferably of substantially 700 nm is coated (Step 9). Thereby, as shown in FIG. 12D, an inorganic insulating film 204 is formed on the organic insulating film 203. In this example, Nanoglass is used as the inorganic insulating film material.

Subsequently, the wafer W is transferred through the vertical transfer unit 22 to the aging unit (DAC), into the processing chamber, (NH₃+H₂O) gas is introduced, and the inorganic insulating film material on the wafer W is subjected to gelling (Step 10).

Next, the wafer W is transferred through the vertical transfer unit 22 to the solvent exchanging unit (DSE), an exchanging chemical liquid is supplied on the wafer W, and thereby a solvent in the insulating film coated on the wafer is exchanged for another solvent (Step 11).

Subsequently, the wafer W is subjected to the low temperature heating in the low temperature heating unit (LHP) (Step 12), the high temperature heating in a low oxygen atmosphere in the low oxygen high temperature heating unit (OHP) (Step 13), the high temperature heating in a low oxygen atmosphere in the low oxygen curing and cooling unit (DCC) followed by cooling to substantially 23° C. (Step 14), and the cooling in the cooling unit (COL) (Step 15).

Then, the wafer W is transferred through the vertical transfer unit 22 to the SOD coating unit (SCT), and an organic insulating film material having a thickness of, for example, from substantially 200 nm to 500 nm, more preferably of substantially 300 nm is spin-coated on the wafer W (Step 16). Thereby, as shown in FIG. 12E, an organic insulating film 205 is formed on the inorganic insulating film 204. In this example, SILK is used as the organic insulating film material.

Subsequently, the wafer W is subjected to the low temperature heating in the low temperature heating unit (LHP) (Step 17), the high temperature heating in a low oxygen atmosphere in the low oxygen high temperature heating unit (OHP) (Step 18), the high temperature heating in a low oxygen atmosphere in the low oxygen curing and cooling unit (DCC) followed by cooling to substantially 23° C. (Step 19), and the cooling process is performed in the cooling unit (COL) (Step 20).

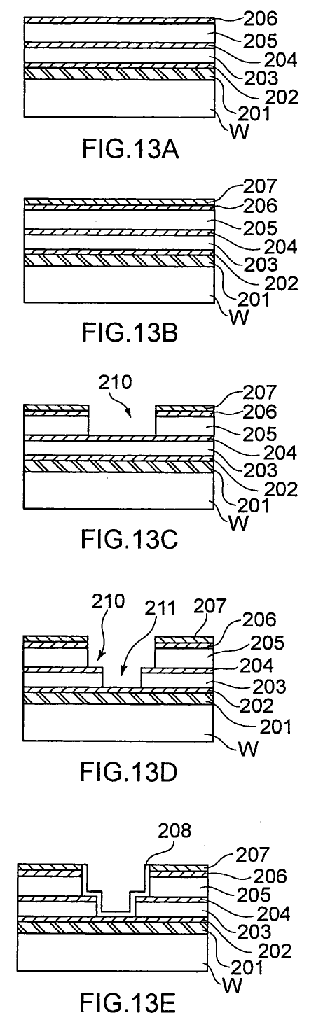

Next, the wafer W is transferred through the vertical transfer unit 22 to the SOD coating unit (SCT), and an inorganic insulating film material having a thickness of, for example, from substantially 300 nm to 1100 nm, more preferably of substantially 700 nm is coated on the wafer W (Step 21). Thereby, as shown in FIG. 13A, an inorganic insulating film 206 is formed on the organic insulating film 205. Thus, on the bottom layer wiring 201 on the wafer W, the organic insulating films and the inorganic insulating films are laminated, and thereby an interlayer insulating film is formed. In this example, Nanoglass is used as the inorganic insulating film material.

Subsequently, the wafer W is transferred through the vertical transfer unit 22 to the aging unit (DAC), (NH₃+H₂O) gas is introduced into the processing chamber and thereby the inorganic insulating film material on the wafer W is subjected to gelling (Step 22).

Next, the wafer W is transferred through the vertical transfer unit 22 to the exchanging chemical liquid coating unit (SCT), an exchanging chemical liquid is supplied on the wafer W and thereby a solvent in the insulating film coated on the wafer is exchanged for another solvent (Step 23).

Subsequently, the wafer W is subjected to the low temperature heating in the low temperature heating unit (LHP) (Step 24), the high temperature heating in a low oxygen atmosphere in the low oxygen high temperature heating unit (OHP) (Step 25), the high temperature heating in a low oxygen atmosphere in the low oxygen curing and cooling unit (DCC) followed by cooling to substantially 23° C. (Step 26), and the cooling process is performed in the cooling unit (COL) (Step 27).

Next, the wafer W is transferred through the transition unit (TRS), the horizontal transfer unit 23 and the load lock chamber 31 into the CVD apparatus 37, and, as shown in FIG. 13B, a hard mask 207 is formed as a protective film for the CMP in the later steps (Step 28).

Then, the wafer W is transferred through the load lock chamber 31, the horizontal transfer unit 23, the transition unit (TRS), the vertical transfer unit 22, the extension unit (EXT) and the wafer transfer mechanism 21 into the cassette CR of the cassette station 10. Thereafter, in a separate apparatus that is not shown, for example, a photolithography process is performed, and a predetermined pattern is developed on the wafer.

Subsequently, the wafer W is transferred to not shown etching apparatus. The hard mask 207, the inorganic insulating film 206 and the organic insulating film 205 are etched by dry etching, using the resist pattern as a mask, as shown in FIG. 13C (Step 29). Thereby, a recessed portion 210 corresponding to the wiring can be formed. In this example, CF₄ gas is used for etching.

After the etching, as mentioned above, by disposing the ashing apparatus and the like in the reduced pressure/increased pressure processing block 12, the resist pattern can be peeled.

Thereafter, the wafer W again undergoes the photolithography process, and as shown in FIG. 13D, the inorganic insulating film 204 and the organic insulating film 203 are etched (Step 30). Thereby, the recessed portion 211 corresponding to a connection plug can be formed. In this example CF₄ gas is used in the etching process.

Then, the wafer W with the resist has been peeled therefrom is transferred through the load lock chamber 31 and the horizontal transfer unit to the CVD apparatus 37, and as shown in FIG. 13E, with the CVD apparatus 37, on an internal sidewall of the recessed portion 210 corresponding to the wiring and the recessed portion 211 corresponding to the connection plug, titanium nitride (TiN) 208 is formed to inhibit copper from diffusing and protecting the sidewall (Step 31). As the sidewall protective film, other than TiN, Ti, TiW, Ta, TaN and WSiN can be used.

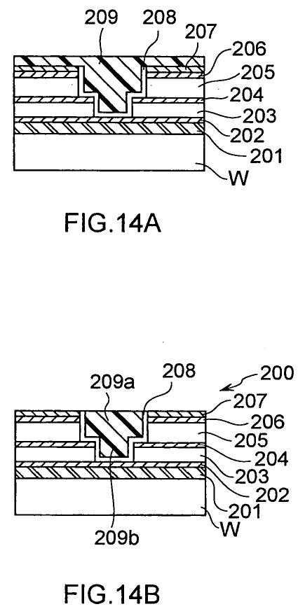

Thereafter, as shown in FIG. 14A, for example, by use of the electroplating, inside of the recessed portion 210 corresponding to the wiring and the recess portion 211 corresponding to the connection plug, copper 209 is buried. Thereafter, copper on the surface portion is polished by use of CMP apparatus that is not shown leaving solely copper in the groove thus a wiring 209a and a connection plug 209b are formed. Thereby, a semiconductor element 200 is formed (Step 32).

As explained above, according to the embodiment, to the atmospheric pressure processing block 11 in which the interlayer insulating film is formed under atmospheric pressure, the reduced pressure/increased pressure processing block 12 in which, under reduced pressure or increased pressure, CVD, cleaning and the like is performed is integrally disposed. Accordingly, in the damascene process in particular, the processing time period can be shortened and the footprint can be reduced.

Furthermore, since a time period from a time when the interlayer insulating film is formed in the atmospheric pressure block to a time when the processing in the reduced pressure/increased pressure processing block 12 is performed is shortened, a condition of the formed insulating film can be well maintained. In particular when the insulating film is a porous film, the absorption of the adjacent insulating film caused by delay in the processing time can also be restrained.

Furthermore, in accordance with the processing processes of various kinds of devices, the respective processing units in the atmospheric pressure processing block 11 can be increased in a vertical direction, and furthermore, the respective processing units in the reduced pressure/increased pressure processing block 12 can be increased in a horizontal direction.

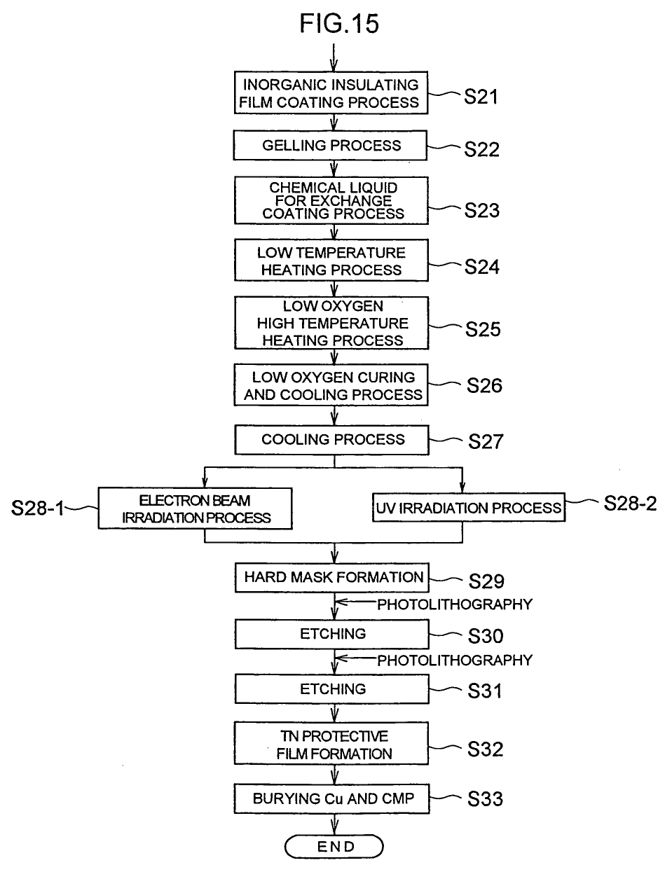

FIG. 15 is a flowchart according to another embodiment. In this embodiment, up to the Step 27, the flow is the same as shown in FIG. 11, and thereby the respective interlayer insulating films 203 through 206 are formed. Thereafter, the electron beam irradiation is performed in the electron beam irradiation unit (EB) 39 (step 28-1). Thereby, for example, the insulating films are rendered porous, and thereby the dielectric constant of the films can be lowered. Alternatively, in order to prevent the pattern collapse and the like from occurring, the film can be made harder, and thereby the quality of the film can be improved.

Furthermore, after the respective interlayer insulating films 203 through 206 are formed, the UV irradiation is performed in the UV irradiation unit (UV) 40 (step 28-2). Thereby, for example, the quality of the film is improved, thus adherence of the insulating film surface can be improved.

Still further, both the electron beam irradiation and UV irradiation can be performed. In this case, either process can be applied first.

After the electron beam irradiation or the UV irradiation is performed, the same steps as shown in the flow chart in FIG. 11 are applied (Step 29 through Step 33).

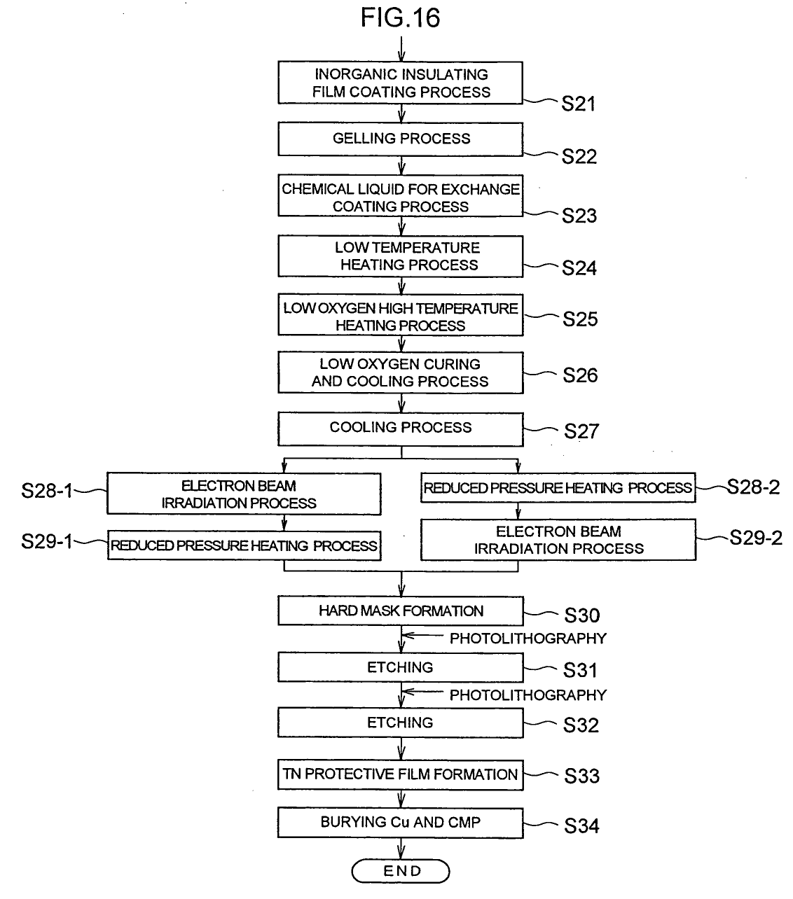

FIG. 16 is a flow chart of still another embodiment. In this embodiment, up to the step 27, the flow is the same as that shown in FIG. 11, and the respective interlayer insulating films 203 through 206 are formed. Thereafter, the electron beam irradiation is performed in the electron beam irradiation unit (EB) 39 (step 28-1). Thereby, for example, the insulating films are rendered porous therefore the dielectric constant of the films can be lowered. Thereafter, heating is performed under reduced pressure in the heat processing apparatus 38 (Step 29-1). Since heating is performed under reduced pressure, rather in a low oxygen atmosphere, even the heating at a temperature of 400° C. or above does not oxidize the substrate. By the heating, the last “burn to harden” (curing) of the insulating film is performed. In the present embodiment, the electron beam processing unit (EB) 39 and the heat processing apparatus 38 are disposed adjacently in the same reduced pressure/increased pressure processing block 12. Accordingly, the electron beam irradiation and the heating can be applied sequentially to the insulating film formed in the atmospheric pressure processing block 11. As a result, the time period for processing can be shortened and an insulating film of high quality can be formed.

Furthermore, by altering an order of the heating and the electron beam irradiation under the reduced pressure, the processing can be performed in an order shown in step 28-2 and step 29-2. In this case, the electron beam irradiation renders the film porous and hardens the film for the last time. According to such flow, the heating and the electron beam irradiation can also be performed successively. As a result, the processing time period can be shortened and an insulating film of high quality can be formed. Furthermore, in order to simultaneously perform the electron beam irradiation and the heating, a susceptor provided with a heater function that allows heating of the wafer W may be disposed in the electron beam processing unit (EB) 39.

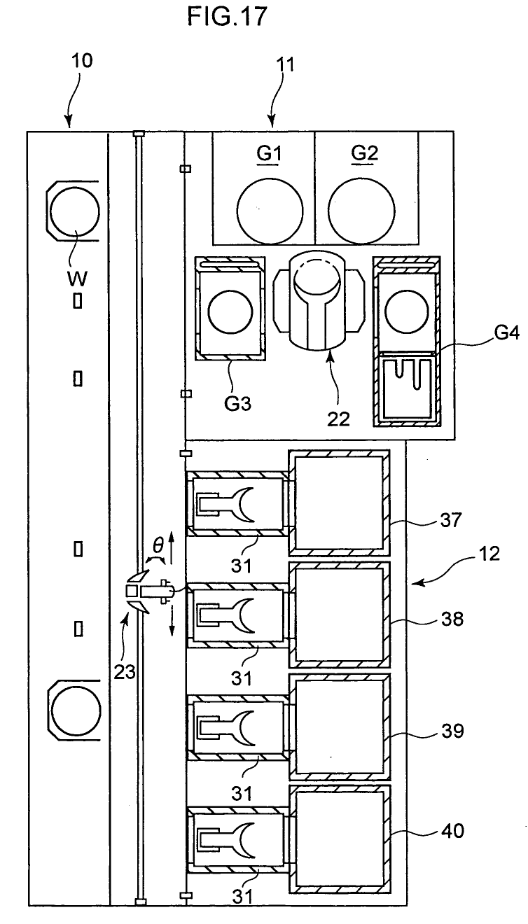

The present invention, without restricting to the above-explained embodiments, can be variously modified. For example, like an insulating film processing system shown in FIG. 17, the atmospheric pressure processing block 11 and the reduced pressure/increased pressure processing block 12 in the above embodiment can be disposed integrally through the cassette station 10.

Also according to such configuration, the time period from a time when the insulating film is formed in the atmospheric pressure processing block 11 to a time when being processed in the reduced pressure/increased pressure processing block 12 can be shortened, and the film of high quality can be maintained.

Furthermore, for example, an inspector inspecting the film thickness and the film quality and the like can be incorporated in the atmospheric pressure processing block 11 or the reduced pressure/increased pressure processing block 12.

Still furthermore, the SOD coating unit (SCT) and the solvent exchanging unit (DSE) may be disposed horizontally side by side, in stead of stacking in two-tiers as shown in FIG. 2,

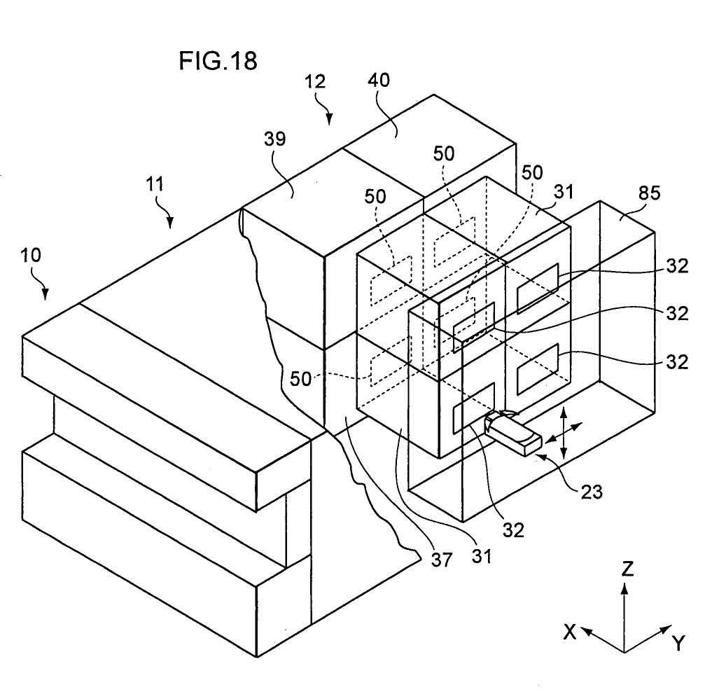

FIG. 18 is a schematic perspective view showing still another embodiment of the insulating film processing system. In the present embodiment, same as the above embodiment, the atmospheric pressure processing block 11 and the reduced pressure/increased pressure processing block 12 are connected. The respective units in the atmospheric pressure processing block 11 may be arranged in a same manner as that shown in, for example, FIG. 1. In the present embodiment, the units in the reduced pressure/increased pressure processing block 12 and the load lock chamber 31 are stacked vertically in two-tiers, which is different from the above. For example, on the CVD apparatus 37, the electron beam irradiation unit (EB) 39 is disposed, and on the heat processing apparatus 38 hidden in the drawing, the UV irradiation unit (UV) 40 is disposed. A load lock chamber 31 is connected to each of these CVD apparatus 37, heat processing apparatus 38, electron beam irradiation unit (EB) 39 and UV irradiation unit (UV) 40, and through an opening 50 thereof, the wafer is transferred. Furthermore, a transfer chamber 85 is connected to the load lock chamber 31, and the transfer chamber 85 is provided with a transfer unit 23 that is movable in an X direction, Y direction and Z direction. The wafer is transferred through an opening portion 32 of the load lock chamber 31 provided between the transfer chamber 85 and the load lock chamber 31. Also according to such system, in the flow shown in FIG. 11, 15 or 16, the insulating film according to the damascene process can be efficiently formed.

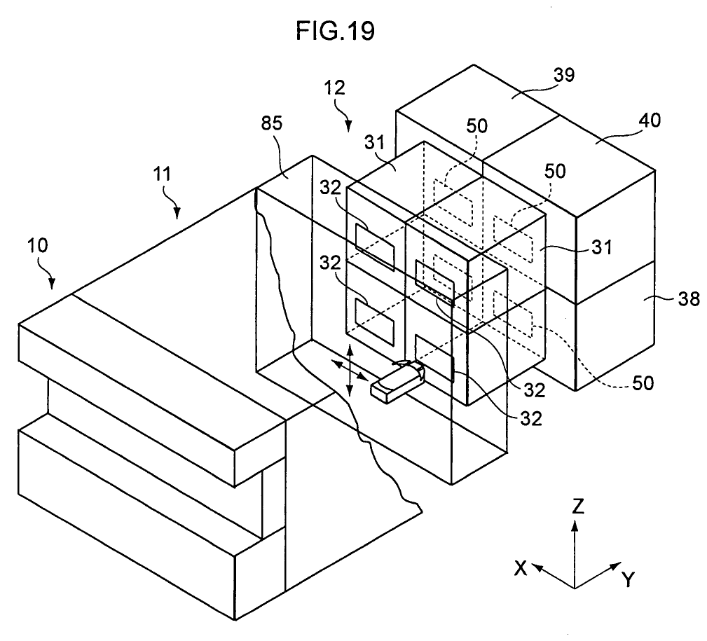

FIG. 19 is also a schematic perspective view showing an insulating film processing system according to another embodiment. Also in the system, to the atmospheric pressure processing block 11, the reduced pressure/increased pressure processing block 12 is connected. In this embodiment, the reduced pressure/increased pressure processing block 12 shown in FIG. 12 is rotated by 90 degree, and thereby to the atmospheric pressure processing block 11, through the transfer chamber 85, the processing units such as the load lock chamber 31, the electron beam irradiation unit (EB) 39 and so on are stacked vertically in two tiers as well. Also in the embodiment, the respective units in the atmospheric pressure processing block 11 can be arranged as shown in, for example, FIG. 1. Furthermore, in this case, the wafer can be transferred between the atmospheric pressure processing block 11 and the reduced pressure/increased pressure processing block 12 in a same manner as above, through the support pins 92 in the transition unit (TRS) in the atmospheric pressure processing block 11. In other words, the wafer can be transferred as shown in FIG. 5.

In such embodiments as shown in FIG. 18 and FIG. 19, the respective reduced pressure/increased pressure processing units and the load lock chambers 31 are multi-tiered and in multi-row. Accordingly, the footprint problem can be largely improved in comparison with the planar configuration.

### INDUSTRIAL APPLICABILITY

As explained above, according to the present invention, the time period for processing necessary forming an insulating film and a wiring can be shortened, and the quality of the coated insulating film can be maintained high.

1. An apparatus for processing a substrate, comprising:
a cassette station, having a plurality of cassettes for accommodating the substrate;
a first processing unit group disposed adjacent to the cassette station, having a plurality of first processing units for forming an insulating film on the substrate under an atmospheric pressure;
a first transfer unit for transferring the substrate to the plurality of first processing units;
a second processing unit group having a plurality of second processing units for processing the substrate with the insulating film being formed thereon, under at least one of a reduced pressure and an increased pressure;
a plurality of load lock chambers connected to each of the plurality of second processing units, capable of controlling an internal pressure thereof; and
a second transfer unit for transferring the substrate between the first processing unit group and the plurality of load lock chambers.

2. The apparatus as set forth in claim 1,
wherein the second processing units are arranged in a horizontal direction, and the second transfer unit transfers the substrate in the horizontal direction.

3. The apparatus as set forth in claim 1,
wherein the second processing units are multi-tiered in a vertical direction, and the second transfer unit transfers the substrate in the vertical direction.

4. The apparatus as set forth in claim 1,
wherein the first processing unit group having at least:
a coating unit for spin-coating a processing solution on the substrate; and
a heating unit for heating the substrate.

5. The apparatus as set forth in claim 1,
wherein the second processing unit group has at least one of an electron beam irradiation unit for curing the insulating film and a UV irradiation unit for reforming a surface state of the insulating film.

6. The apparatus as set forth in claim 5,
wherein the second processing unit group has a CVD apparatus.

7. The apparatus as set forth in claim 1, further comprising:
a transfer arm for transferring the substrate between the second processing unit and the load lock chamber.

8. The apparatus as set forth in claim 1, further comprising:
a plurality of pins, disposed at least in one of the plurality of processing units in the first processing unit group, for transferring t he substrate between the first transfer unit and the second transfer unit.

9. The apparatus as set forth in claim 8, further comprising:
a cassette station disposed adjacent to the first processing unit group having a plurality of cassettes being linearly arranged for accommodating the substrates; and
means for moving the plurality of pins in a direction in which the plurality of cassettes are arranged.

10. An apparatus for processing a substrate comprising:
a first processing unit group having a plurality of first processing units for forming an insulating film on the substrate under an atmospheric pressure;
a second processing unit group having a plurality of second processing units for processing the substrate with the insulating film being formed thereon, under at least one of a reduced pressure and an increased pressure;
a plurality of load lock chambers connected to each of the plurality of second processing units, capable of controlling an internal pressure thereof;
a transfer unit for transferring the substrate between the first processing unit group and the plurality of load lock chambers;
a transfer arm disposed in the load lock chamber for transferring the substrate being transferred by the transfer unit to the second processing unit; and
a controller for controlling a processing order such that after the insulating film is formed in the plurality of the first processing units, the transfer unit transfers the substrate to the load lock chamber and the transfer arm transfers the substrate to the second processing unit, so that the substrate is processed in the second processing unit.

11. The apparatus as set forth in claim 10,
wherein the first processing unit group having:
a coating unit for spin coating a processing solution onto the substrate; and
a heating unit for heating the substrate.

12. The apparatus as set forth in claim 10,
wherein the second processing unit group has at least one of an electron beam irradiation unit for hardening the insulating film and a UV irradiation unit for reforming a surface state of the insulating film.

13. An apparatus for processing a substrate, comprising:
a first processing unit group having a plurality of first processing units for forming an insulating film on the substrate under an atmospheric pressure;
a second processing unit group having a plurality of second processing units for processing the substrate with the insulating film being formed thereon, under at least one of a reduced pressure and an increased pressure;
a plurality of load lock chambers connected to each of the plurality of second processing units, with an inside pressure thereof capable of being controlled; and
a cassette station disposed adjacent to the first processing units having a plurality of cassettes being linearly arranged for accommodating the substrates.

14. A method of processing a substrate, comprising:
forming an insulating film on the substrate under an atmospheric pressure in a first processing unit group;
transferring the substrate to an intermediate delivery portion disposed in the first processing unit group and transfers the substrate to a second processing unit group disposed adjacent to the first processing unit group;
transferring the substrate from the intermediate delivery portion to the second processing unit group; and
irradiating an electron beam on the substrate under a reduced pressure in the second processing unit group.

15. The method as set forth in claim 14, further comprising:
heating the substrate with the insulating film being formed thereon under the atmospheric pressure in the first processing unit group.

16. The method as set forth in claim 14, further comprising:
heating the substrate with the insulating film being formed thereon under the reduced pressure in the second processing unit group.
